(19) United States
(12) Patent Application Publication
(10) Pub. No.: US 2024/0295601 A1
(43) Pub. Date: Sep. 5, 2024

(54) DISTRIBUTED BUILT-IN SELF-TEST AND MONITORING

(71) Applicant: QUALCOMM Incorporated, San Diego, CA (US)

(72) Inventors: Zdravko LUKIC, San Diego, CA (US); Raymond ROSIK, San Diego, CA (US); Brett WALKER, Rancho Santa Fe, CA (US); Huiqiao HE, Singapore (SG)

(21) Appl. No.: 18/177,470

(22) Filed: Mar. 2, 2023

(51) Int. Cl. G01R 31/28; G01R 31/3167; G01R 31/3187; H03M 1/10

(52) U.S. Cl. CPC G01R 31/2884; G01R 31/3167; G01R 31/3187; H03M 1/1071

(57) ABSTRACT

Aspects of the present disclosure provide techniques and apparatus for distributed built-in self-test. An example method of testing circuitry includes testing, in a first occasion, a first electrical circuit, having a first component, using at least a second component of a second electrical circuit; and testing, in a second occasion, the second electrical circuit using at least the first component of the first electrical circuit.

### BACKGROUND

### Field of the Disclosure

Certain aspects of the present disclosure generally relate to electronic components, and more particularly to a built-in self-test architecture.

### Description of Related Art

Certain mechanisms (e.g., devices, machines, vehicles, and/or software) undergo built-in self-tests (BISTs), for example, in any of various applications, such as automotive, aircraft, spacecraft, watercraft, medical, electronic, and/or military applications. A BIST is where a mechanism tests itself to ensure the mechanism is operating as expected. The BIST may be performed to ensure high reliability of the mechanism's performance. In some cases, the BIST may be performed to reduce repair cycle times, testing during manufacture, and/or testing with external test equipment. The BIST may be performed to comply with certain functional safety standards, such as ISO 26262 associated with automotive applications as provided by the International Organization for Standardization (ISO). As an example, a functional safety standard for certain automotive applications may provide that a voltage monitor, which monitors whether a voltage regulator is outputting an overvoltage or undervoltage, occasionally undergoes a BIST to ensure the voltage monitor is properly identifying such an overvoltage or undervoltage and not in a stuck-at low state, for example.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure provide a method of testing circuitry. The method generally includes testing, in a first occasion, a first electrical circuit, having a first component, using at least a second component of a second electrical circuit; and testing, in a second occasion, the second electrical circuit using at least the first component of the first electrical circuit.

Certain aspects of the present disclosure provide a method of testing circuitry. The method generally includes testing, in a first occasion, a first electrical circuit, having a first electrical component, using at least a second component of a second electrical circuit; and monitoring a signal output by a third electrical circuit using the first electrical circuit in response to detecting a successful test from the testing.

Certain aspects of the present disclosure provide an apparatus for testing circuitry. The apparatus generally includes a first electrical circuit, a second electrical circuit, a memory, and a processor. The first electrical circuit has a first component, and the second electrical circuit has a second component selectively coupled to the first electrical circuit. The processor is configured to test, in a first occasion, the first electrical circuit using at least the second component; and test, in a second occasion, the second electrical circuit using at least the first component.

Certain aspects of the present disclosure provide an apparatus. The apparatus generally includes a first electrical circuit, a second electrical circuit, a third electrical circuit. The first electrical circuit has a first digital-to-analog converter (DAC) and a first comparator, wherein the first DAC is coupled to a first input of the first comparator. The second electrical circuit has a second DAC selectively coupled to a second input of the first comparator. The third electrical circuit has an output selectively coupled to the second input of the first comparator.

Certain aspects of the present disclosure provide an apparatus for testing circuitry. The apparatus generally includes means for testing, in a first occasion, a first electrical circuit, having a first component, using at least a second component of a second electrical circuit; and means for testing, in a second occasion, the second electrical circuit using at least the first component of the first electrical circuit.

Certain aspects of the present disclosure provide an apparatus for testing circuitry. The apparatus generally includes means for testing, in a first occasion, a first electrical circuit, having a first electrical component, using at least a second component of a second electrical circuit; and means for monitoring a signal output by a third electrical circuit using the first electrical circuit in response to detecting a successful test from the testing.

Certain aspects of the present disclosure provide a computer-readable medium having instructions stored thereon for testing, in a first occasion, a first electrical circuit, having a first component, using at least a second component of a second electrical circuit; and testing, in a second occasion, the second electrical circuit using at least the first component of the first electrical circuit.

Certain aspects of the present disclosure provide a computer-readable medium having instructions stored thereon for testing, in a first occasion, a first electrical circuit, having a first electrical component, using at least a second component of a second electrical circuit; and monitoring a signal output by a third electrical circuit using the first electrical circuit in response to detecting a successful test from the testing.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example vehicle with a vehicle control system.

FIG. 2 is a block diagram of example components and interconnections in a system-on-a-chip (SoC).

FIG. 3 is a block diagram of an example of a circuit architecture with built-in self-test (BIST).

FIG. 4 is a block diagram of an example circuit having a distributed BIST architecture.

FIG. 5 is a block diagram illustrating example interconnections among monitoring circuits for distributed BIST.

FIG. 6 is a more detailed block diagram illustrating example interconnections among the monitoring circuits depicted in FIG. 5.

FIG. 7 is a timing diagram illustrating example timelines for time division multiplexing the BIST and monitoring across multiple circuits.

FIG. 8 is a flow diagram depicting example operations for testing circuitry.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to methods and apparatus for distributed built-in self-test (BIST). As used herein, a distributed BIST may refer to where a component of a circuit is shared (distributed) with one or more other circuits to perform BISTs on the other circuit(s).

To verify correct operation of certain circuits and/or ensure the detection of latent faults, a circuit may occasionally undergo a BIST. For example, electrical components associated with automotive safety systems (e.g., certain advanced driver assistance system (ADAS) and/or automated driving (AD) systems), may undergo BISTs to ensure the correct operation of such electrical components, such as memory, a processor, control logic, a power management circuit, a voltage regulator, current regulator, etc. ADAS and/or AD systems have generally increased driver and passenger safety, but can cause harm to passengers or bystanders if these systems malfunction. Measures to detect such faults are designed in line with a particular automotive safety integrity level (ASIL), for example, as per functional safety standard, such as ISO 26262 for automotive applications as provided by the International Organization for Standardization (ISO). It will be appreciated that BISTs may be performed in any of various applications, such as automotive, aircraft, spacecraft, watercraft, medical, electronic, and/or military applications.

For example, a power management circuit (such as a power management integrated circuit (PMIC)) may have a monitoring circuit (e.g., an overvoltage protection (OVP) monitor) that monitors the signal output by a voltage regulator for any over-voltages and/or under-voltages. The monitoring circuit may use a comparator that compares the output signal of the voltage regulator to a reference voltage, which may be output by a digital-to-analog-converter (DAC), for example. A BIST may also be occasionally performed on the monitoring circuit to verify that such circuitry is operating as expected, for example, properly detecting an overvoltage and/or an undervoltage (or overcurrent and/or undercurrent). To perform such a BIST, a reference generator, which may be implemented by two (or more) DACs, may output certain voltages to the comparator (e.g., an overvoltage, an undervoltage, and a reference voltage, which may vary depending on the voltage being tested). The BIST may check that the monitoring circuit correctly identifies an over-voltage and/or an under-voltage. As each DAC occupies space of the integrated circuit, having two DACs for each monitoring circuit equates to a substantial amount of space dedicated to BIST circuitry, which is only occasionally used, especially, when a PMIC may be equipped with upwards of forty separate monitoring cells of the monitoring circuit, for example.

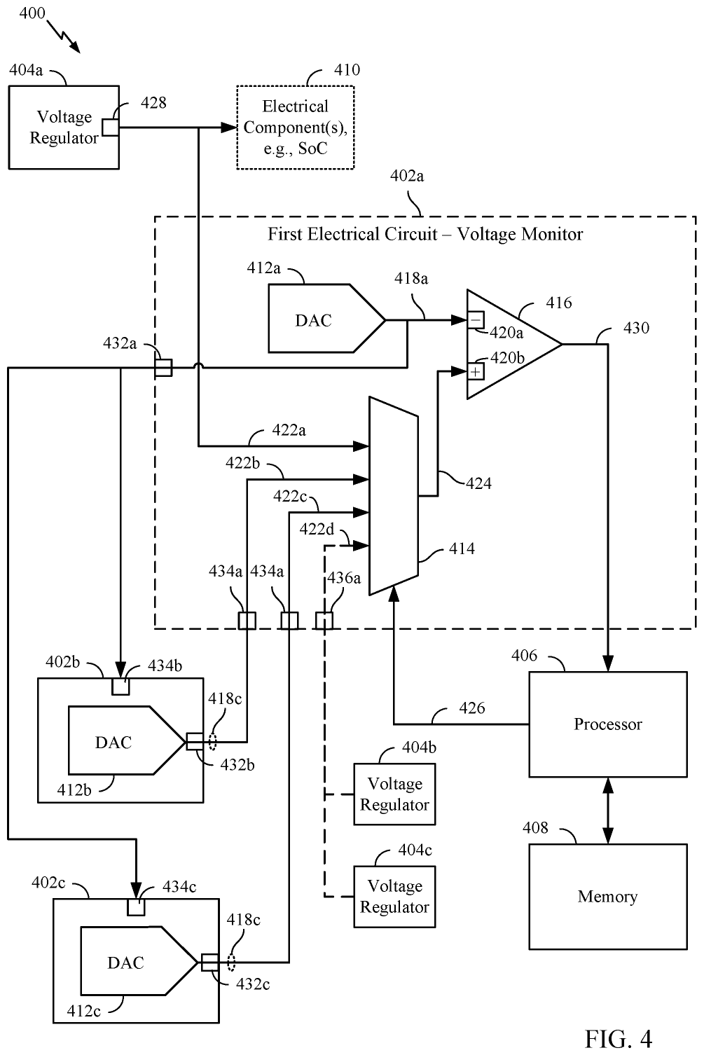

Aspects of the present disclosure provide methods and apparatus that share components across adjacent circuits to facilitate BISTs, to save space. For example, to perform a BIST on a voltage (and/or current) monitoring circuit, a DAC from an adjacent voltage monitoring circuit may be used to provide one of the signals to a comparator of the voltage monitoring circuit undergoing the test. The local DAC of the voltage monitoring circuit may provide the other signal to the same comparator. In other words, the two comparator signals may be provided from DACs from two different monitoring circuits: the local monitoring circuit with the comparator and an adjacent monitoring circuit. Each of the DACs of the monitoring circuits may be selectively coupled to a neighboring monitoring circuit, as further described herein with respect to FIGS. 4-6. It will be appreciated that other components may be shared among adjacent circuits for performing BISTs, such as functional safety standard compliant BISTs, and that the sharing of DACs among monitoring circuits is merely an example of the present disclosure.

Such a distributed testing architecture may enable an efficient circuit design that eliminates several DACs (e.g., at least one in each monitoring cell) that may only be occasionally used for BIST. In some cases, the distributed testing architecture described herein may allow for a reduction in chip size due to the shared components, such as the DACs. In certain cases, the distributed testing architecture described herein may allow for the chip size savings facilitated by the shared components to be used for other resources to facilitate a more robust chip package.

### Example Vehicle Control System

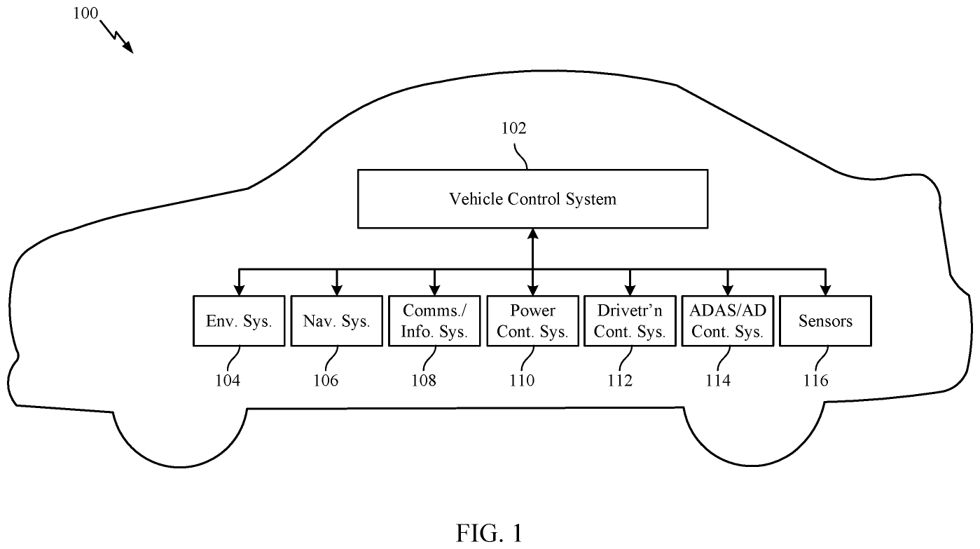

FIG. 1 is a block diagram of an example vehicle 100 including a vehicle control system 102 and various sensors suitable for controlling certain systems, such as an ADAS, an AD, and/or an in-vehicle infotainment (IVI). The vehicle 100 may refer to a means of carrying or transporting something (e.g., a person and/or cargo). In some aspects, the vehicle 100 may represent a motor vehicle, such as a car, van, truck, semitruck, motorcycle, motorbike, moped, electric bicycle, etc. The vehicle 100 may be a series production road vehicle having safety-related systems that include one or more electrical and/or electronic systems, as further described herein. The vehicle 100 may use an internal combustion engine, an electric motor, or a hybrid propulsion system (e.g., a combination of an engine and an electric motor) for propulsion. In some cases, the vehicle 100 may have one or more electrical and/or electronic systems that comply with certain functional safety standards, such as ISO 26262 as provided by the ISO.

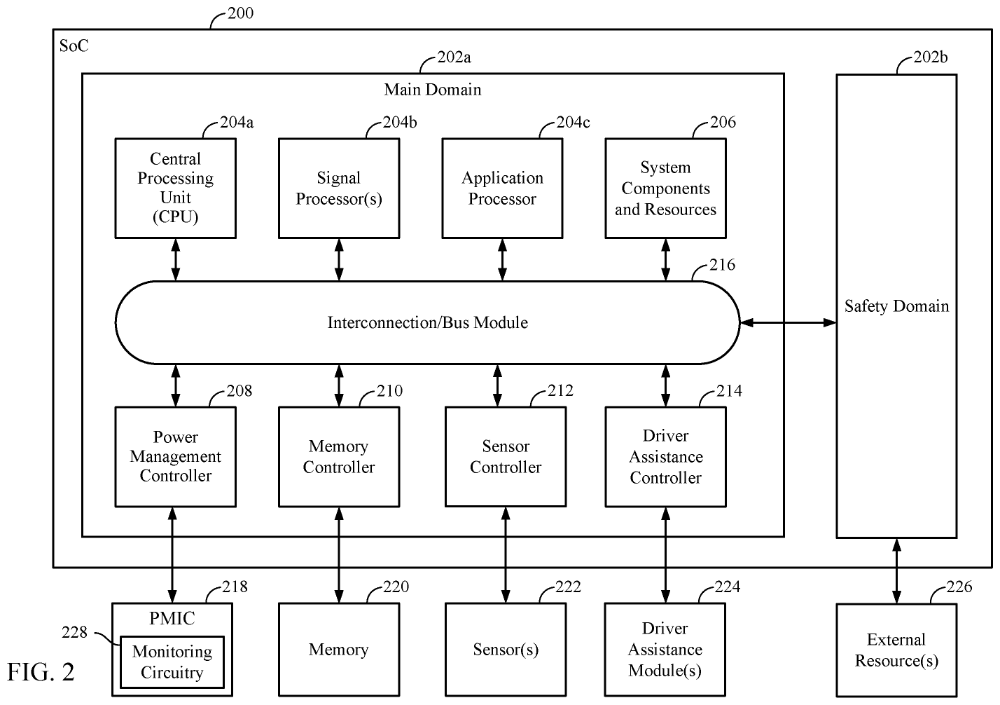

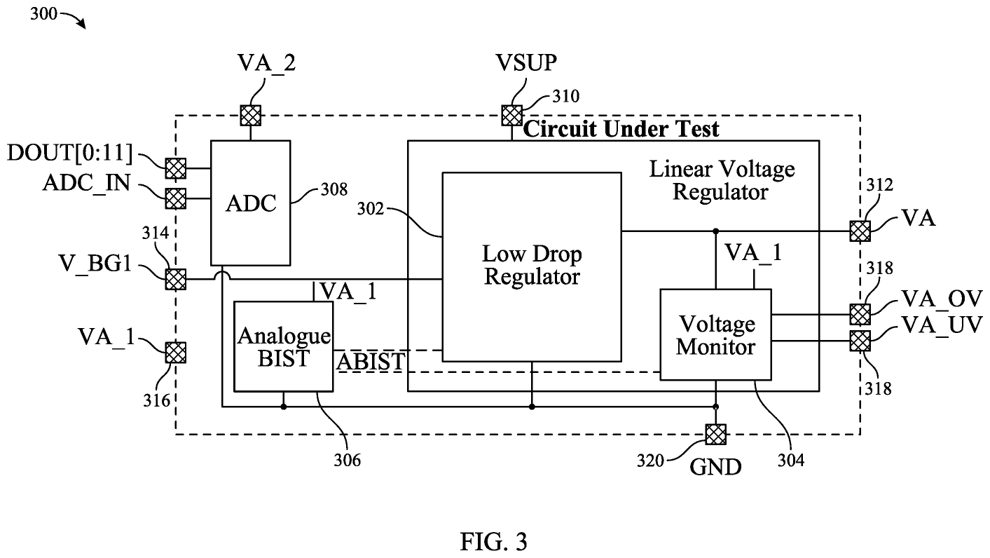

The vehicle control system 102 may include one or more computing devices having system-on-chips (SoCs) (e.g., one or more electronic control units (ECUs)) as further described herein with respect to FIGS. 2 and 3. The vehicle control system 102 may be coupled to a variety of vehicle systems and subsystems, such as an environmental system 104 (e.g., an air conditioning and/or heating system), a navigation system 106, a communications and/or infotainment system 108, a power control system 110, a drivetrain control system 112, a driver assistance and/or automated driving control system 114, and/or a variety of sensors 116. Each of the vehicle systems and sensors 102-116 may communicate with one or more other systems via one or more communication links, which may include wired communication links (e.g., a Controller Area Network (CAN) protocol compliant bus, Universal Serial Bus (USB) connection, Ethernet connection, universal asynchronous receiver-transmitter (UART), etc.) and/or wireless communication links (e.g., a Wi-Fi® link, Bluetooth® link, ZigBee® link, ANT+® link, Evolved Universal Terrestrial Radio Access (E-UTRA), Fifth Generation (5G) New Radio, etc.).

The vehicle control system 102 may perform certain operations associated with any of the vehicle systems and subsystems. For example, the vehicle control system 102 may control or initiate the power-on and/or shutdown sequence for any of the vehicle systems and subsystems. The vehicle control system 102 may monitor for errors associated with any of the vehicle systems and subsystems, and in some cases, the vehicle control system 102 may store the errors for vehicle diagnostics. In response to any errors detected, the vehicle control system 102 may perform certain actions, such as shutting down the affected system or transferring some of the affected operations to be performed at a different vehicle system. The vehicle control system 102 may monitor the power levels supplied to any of the vehicle systems and subsystems and ensure that the power levels supplied satisfy the operating specifications for any of the vehicle systems and subsystems.

The environmental system 104 may control the cooling and/or heating systems associated the vehicle 100. For example, the vehicle 100 may have an air conditioning system, a heating system, heated or cooled seat(s), and/or a heated steering wheel; and the environmental system 104 may adjust the temperature according to user (or default) settings for the respective cooling and/or heating components. The navigation system 106 may show the vehicle's location on a map and provide navigation information, such as directions to a destination, via a display (not shown).

The communications and/or infotainment system 108 may allow the user to access various information (e.g., navigation information, interior or exterior environmental information, ADAS information, etc.), applications, and/or entertainment or media content, such as music and/or videos. The communications and/or infotainment system 108 may allow the user to update or access settings associated with a variety of systems, such as the environmental system 104, the navigation system 106, ADAS, vehicle settings, etc. The communications and/or infotainment system 108 may allow the user and/or vehicle 100 to wirelessly communicate via an integrated modem of the vehicle or via the user's wireless communication device (e.g., a smartphone or tablet).

The power control system 110 may control the components that output power to move the vehicle, such as an internal combustion engine (e.g., adjusting the air-fuel ratio, boost pressure, valve timing, etc.), an electric power system (e.g., controlling regenerative braking, battery power output, battery charging, and/or battery cooling, etc.), and/or a hybrid power system (e.g., controlling regenerative braking, switching between battery power and engine power, battery charging, battery cooling, etc.). The drivetrain control system 112 may control the various components of the vehicle 100 that deliver power to the drive wheels. For example, the drivetrain control system 112 may control gear shifting in an automatic transmission. For a four-wheel drive vehicle, the drivetrain control system 112 may control the power ratio applied to the front and rear drive wheels.

The driver assistance and/or automated driving control system 114 may control various driver assistance features and functions, such as adaptive cruise control, automated lane detection, lane departure warning, automated steering, automated braking, and automated collision avoidance. The driver assistance and/or automated driving control system 114 may control automated driving at various levels of automation, such as any of the Society of Automotive Engineers (SAE) levels 1 through 5.

The variety of sensors 116 coupled to the vehicle control system 102 may include any of the vehicle's speedometer, a wheel speed sensor, a torquemeter, a turbine speed sensor, a variable reluctance sensor, a sonar system, a radar system, an air-fuel ratio meter, a water-in-fuel sensor, an oxygen sensor, a crankshaft position sensor, a curb feeler, a temperature sensor, a Hall effect sensor, a manifold absolute pressure sensor, various fluid sensors (e.g., engine coolant sensor, transmission fluid sensor, etc.), a tire-pressure monitoring sensor, a mass airflow sensor, a speed sensor, a blind spot monitoring sensor, a parking sensor, cameras, microphones, accelerometers, compasses, a global navigation satellite system (GNSS) receiver (e.g., a global positioning system (GPS) receiver or a Galileo receiver), and other similar sensors for monitoring physical or environmental conditions in and around the vehicle.

The aforementioned systems are presented merely as examples, and vehicles may include one or more additional systems that are not illustrated for clarity. Additional systems may include systems related additional other functions of the vehicular system, including instrumentation, airbags, cruise control, other engine systems, stability control parking systems, tire pressure monitoring, antilock braking, active suspension, battery level and/or management, and a variety of other systems.

### Example System-On-A-Chip

The term “system-on-a-chip” (SoC) is used herein to refer to a single integrated circuit (IC) chip that contains multiple resources and/or processors integrated on a single substrate or in a single package. A single SoC may contain circuitry for digital, analog, mixed-signal, and radio-frequency functions. A single SoC may also include any number of general purpose and/or specialized processors (digital signal processors, modem processors, video processors, etc.), memory blocks (e.g., ROM, RAM, flash, etc.), and resources (e.g., timers, voltage regulators, oscillators, etc.). A SoC may also include software for controlling the integrated resources and processors, as well as for controlling peripheral devices.

FIG. 2 is a block diagram of example components and interconnections in a system-on-a-chip (SoC) 200 suitable for implementing various aspects of the present disclosure. The SoC 200 may include multiple processing domains having, for example, a main domain 202a and a safety domain 202b (also referred to as a “safety island (SAIL)”). The main domain 202a may be configured to support (or capable of performing) vehicle operations (e.g., driver assistance and/or automated driving operations, features, etc.) up to a specific automotive safety integrity level (ASIL), and the safety domain 202b may be configured to support (or capable of performing) vehicle operations up to a lower, the same, or a higher ASIL than the main domain 202a. For example, the main domain 202a may be configured to support (or capable of performing) vehicle operations up to an ASIL B, and the safety domain 202b may be configured to support vehicle operations up to an ASIL D. In some cases, the main domain 202a may be configured to support (or capable of performing) vehicle operations up to an ASIL A, B, C, or D; and the safety domain 202b may be configured to support vehicle operations up to a different ASIL than the main domain 202a. In certain cases, the main domain 202a and the safety domain 202b may be configured to support (or capable of performing) vehicle operations at the same ASIL (e.g., ASIL D). The main domain 202a and the safety domain 202b may be configured to support (or capable of performing) vehicle operations at different ASILs.

The ASILs may be defined in a specific safety standard, such as ISO 26262. For example, the ASILs may provide a risk classification scheme for certain electrical and electronic systems of road vehicles. ISO 26262 provides four ASILs including ASIL A, ASIL B, ASIL C, and ASIL D. ASIL D is the highest classification and corresponds to the highest level of safety measures for avoiding an unreasonable residual risk, and ASIL A is the lowest classification and corresponds to the lowest level of safety measures.

In certain aspects, the SoC 200 may be included in a computing device (e.g., an ECU) in a vehicle control system. The SoC 200 may control any of the systems described herein with respect FIG. 1. For example, the SoC 200 may be configured to control an ADAS/AD system, such as the driver assistance and/or automated driving control system 114 described herein with respect to FIG. 1. In certain aspects, the SoC 200 may be in communication with other ECU(s) in a vehicle control system, such as the control system described herein with respect to FIG. 1. For example, the main domain 202a may control the environmental system, the infotainment system, and driver assistance features up to a certain ASIL; and the safety domain 202b may control driver assistance features up to a certain ASIL, which may typically be higher than the main domain 202a.

The main domain 202a and/or safety domain 202b may include a number of heterogeneous processors 204a-c (collectively processors 204), such as a central processing unit (CPU) 204a, signal processor(s) or other specialized processor(s) 204b (e.g., a digital signal processor, an image signal processor, a neural network signal processor, computer vision processor, a graphics processing unit (GPU), etc.), and/or an application processor 204c. Each processor 204 may include one or more cores, and each processor/core may perform operations independent of the other processors/cores. Each processor 204 may be part of a subsystem (not shown) including one or more processors, caches, etc. configured to handle certain types of tasks or computations. It should be noted that the main domain 202a and/or safety domain 202b may include additional processors (not shown) or may include fewer processors (not shown). The main domain 202a and/or safety domain 202b may include other processors (e.g., a graphics processing unit, a vision processing unit, etc.) in addition to or instead of those illustrated.

The main domain 202a and/or safety domain 202b may include system components and resources 206 for performing certain specialized operations, such as analog-to-digital conversions and/or wireless data transmissions. The system components and resources 206 may include components such as voltage regulators, oscillators, phase-locked loops, peripheral bridges, data controllers, system controllers, access ports, timers, and other similar components used to support the processors and software clients running on the SoC 200. The system components and resources 206 may include circuitry for interfacing with peripheral devices, such as cameras, electronic displays, wireless communication devices, external memory chips, etc.

The main domain 202a and/or safety domain 202b may further include a power management controller 208, a memory controller 210 (e.g., a dynamic random access memory (DRAM) memory controller and/or a non-volatile memory controller), a sensor controller 212, and/or a driver assistance controller 214. The main domain 202a and/or safety domain 202b may also include an input/output (IO) module (not shown) for communicating with resources external to the SoC, such as a clock and a voltage regulator, each of which may be shared by two or more of the internal SoC components. The IO module may include a general purpose IO (GPIO) interface, for example. In certain aspects, each of the main domain 202a and the safety domain 202b may have a separate clock to facilitate independent operability.

The processors 204 of the main domain 202a may be interconnected to the system components and resources 206, the power management controller 208, the memory controller 210, the sensor controller 212, the driver assistance controller 214, other system components, and/or the safety domain 202b via an interconnection/bus module 216, which may include an array of reconfigurable logic gates and/or implement a bus architecture (e.g., CoreConnect, advanced microcontroller bus architecture (AMBA), etc.). Communications may be provided by advanced interconnects, such as high performance networks-on-chip (NoCs).

The interconnection/bus module 216 may include or provide a bus mastering system configured to grant SoC components (e.g., processors, peripherals, etc.) exclusive control of the bus (e.g., to transfer data) for a set duration, number of operations, number of bytes, etc. In certain aspects, the bus module 216 may include a direct memory access (DMA) controller (not shown) that enables components connected to the bus module 216 to operate as a master component and initiate memory transactions. The bus module 216 may implement an arbitration scheme to prevent multiple master components from attempting to drive the bus simultaneously.

The power management controller 208 may manage the power supplied to the main domain 202a from a PMIC 218, which may be representative of one or more PMIC(s). The power management may be separate and independent between the main domain 202a and the safety domain 202b. In certain aspects, the PMIC 218 may include monitoring circuitry 228 that monitors the correct operation of the PMIC 218 (or certain components of the PMIC 218) as further described herein with respect to FIGS. 3 and 4. In certain cases, the monitoring circuitry 228 may undergo a BIST to ensure the monitoring circuitry 228 is operating as expected, for example, correctly identifying an overvoltage or undervoltage (or an overcurrent or an undercurrent). To perform the BIST associated with the monitoring circuitry 228, a distributed BIST architecture may be performed as further described herein with respect to FIG. 4.

The memory controller 210 may be a specialized hardware module configured to manage the flow of data to and from a memory 220. The memory controller 210 may include logic for interfacing with the memory 220, such as selecting a row and column in a cell array of the memory 220 corresponding to a memory location, reading or writing data to the memory location, etc. The memory 220 may be an on-chip component (e.g., on the substrate, die, integrated chip, etc.) of the SoC 200, or alternatively (as shown) an off-chip component.

The sensor controller 212 may manage the sensor data received from various sensors 222, such as the sensors 116. The sensor controller 212 may include circuitry for interfacing with the sensors 222. For example, the sensor controller 212 may receive sensor data from a tire pressure monitoring system and/or a radar sensor used for adaptive cruise control.

The driver assistance controller 214 may control certain driver assistance functions via a driver assistance module 224 (e.g., one or more actuators, relays, switches, etc.). For example, the driver assistance controller 214 may control the adaptive cruise control by controlling actuators coupled to the engine and/or braking system. In some cases, the driver assistance controller 214 may perform automated steering by controlling actuators attached to the steering system. It will be appreciated that the driver assistance controller 214 is merely an example, and the main domain 202a and/or the safety domain 202b may include a controller that interfaces with automated driving components in addition to or instead of the driver assistance controller 214.

The SoC 200 may also include additional hardware and/or software components that are suitable for collecting sensor data from sensors, including speakers, user interface elements (e.g., input buttons, touch screen display, etc.), microphone arrays, sensors for monitoring physical conditions (e.g., location, direction, motion, orientation, vibration, pressure, temperature, etc.), cameras, compasses, GPS receivers, communications circuitry (e.g., Bluetooth®, wireless local area network (WLAN), Long Term Evolution (LTE), Fifth Generation New Radio (5G NR), etc.), and other well-known components (e.g., accelerometer, etc.) of modern electronic devices.

Each of the processing domains may operate independently of the other domains. In some cases, each of the processing domains may be coupled to separate and independent external resources, such as a PMIC, memory, sensor(s), and driver assistance module(s). A particular external resource may be designed in accordance with an ASIL corresponding to the particular ASIL associated with the main domain 202a and/or the safety domain 202b to which the external resource is coupled. For example, the PMIC 218 may have the same ASIL as the main domain 202a, and the PMIC that provides power to the safety domain 202b may have the same ASIL as the safety domain 202b. The safety domain 202b may include the same or different processing resources and components as the main domain 202a as described herein with respect to the main domain 202a. For example, the safety domain 202b may include the processors 204, the system components and resources 206, the power management controller 208, the memory controller 210, the sensor controller 212, and the driver assistance controller 214. The safety domain 202b may be coupled to certain external resource(s) 226, which may be representative of a PMIC, memory, sensors, and/or driver assistance module, for example, as described herein with respect to the main domain 202a.

It will be appreciated that the SoC 200 having separate domains, such as a main domain and a safety domain, is merely an example. Aspects of the present disclosure may applied to performing a distributed BIST as further described herein for other electrical component(s), such as a SoC having a single domain or more than two domains. In addition to the SoC 200 discussed above, various aspects may be implemented in a wide variety of computing systems, which may include a single processor, multiple processors, multicore processors, or any combination thereof.

### Example Built-In Self-Test

FIG. 3 is a block diagram of an example circuit architecture 300 of an analog circuit, such as a power supply or PMIC (e.g., the PMIC 218), having a BIST. For analog BIST, the analog circuit (e.g., a diagnostic or monitoring circuit) may be put into and out of fault scenarios by injecting certain currents or voltages into the circuit to ensure the circuit can switch to fault and non-fault (successful) states. To perform an analog BIST, a voltage representative of a fault may be injected into the circuit in a first occasion, and another voltage representative of successful operation may be injected into the circuit in a second occasion. In this example, the circuit architecture 300 may include a voltage regulator 302, a voltage monitor 304, an analog BIST circuit 306, and an analog-to-digital converter (ADC) 308. Each of the components may be coupled to reference potential node 320 (e.g., electrical ground (GND)).

The voltage regulator 302 may be a low dropout (LDO) voltage regulator, for example. The voltage regulator 302 may receive a supply voltage via a supply input 310 (VSUP) and output a direct current (DC) signal at a specified voltage via an output 312 (VA). In some cases, the voltage regulator 302 may receive a bandgap reference voltage supplied externally to the circuit for the LDO to use as its reference voltage via a reference input 314 (V_BG1).

The voltage monitor 304 may have a first input coupled to the output 312 and a second input coupled to a reference voltage 316 (VA_1), which may also function as the power supply voltage for the voltage monitor. The voltage monitor 304 may compare the voltage of the signal output by the voltage regulator 302 to the reference voltage. The voltage monitor 304 may indicate whether there is an overvoltage fault or an undervoltage fault via the fault outputs 318 (VA_OV and VA_UV).

The analog BIST circuit 306 may occasionally test whether the voltage regulator 302 and/or the voltage monitor 304 are operating as expected. For example, the analog BIST circuit 306 may output, to the voltage monitor 304, a signal that mimics (or simulates) an overvoltage or undervoltage to test if the voltage monitor 304 properly detects such a fault.

The ADC 308 may be coupled to other circuitry (not shown), such as a sensor (e.g., a temperature sensor, accelerometer, speed sensor, rain sensor, ADAS sensor, etc.), to collect data associated with the analog circuit (e.g., for testing or monitoring purposes).

According to failure mode effects/diagnostics analysis (FMEDA), the fault models for voltage or current monitoring may include a comparator being stuck at outputting a certain digital signal, such as a stuck-at-low fault or stuck-at-high fault. With a stuck-at-low fault, the comparator may be unable to detect an overvoltage or overcurrent fault occurrence. With a stuck-at-high fault, the comparator may be persistently indicating an overvoltage or overcurrent fault. An analog BIST operation may be occasionally performed to test if a comparator circuit is working as expected by swapping the measurement signal with an auxiliary reference signal that is expected to trigger a state change of the comparator. The auxiliary reference signal may be provided by a DAC, such that two DACs may be used to perform a BIST, for example. Having two dedicated DACs for each voltage monitor can use a substantial amount of circuit space, where only one DAC is occasionally used for BISTs. Once the BIST check is completed, the voltage monitor may be reconfigured to monitor the output of the voltage regulator. Aspects of the present disclosure may be applied to other types of BISTs for circuits such as various monitoring circuits including a current monitor, temperature monitor, etc.

### Example Distributed Built-In Self-Test

FIG. 4 is a block diagram of an example circuit 400 having a distributed BIST architecture. In this example, the circuit 400 may include a first electrical circuit 402a, a second electrical circuit 402b, and in some cases, a third electrical circuit 402c (collectively electrical circuits 402). The circuit 400 may also include one or more fourth electrical circuits 404a-c, and in some cases, a processor 406, and a memory 408.

Each of the electrical circuits 402 may be a circuit that undergoes a built-in self-test, for example, in compliance with a functional safety standard such as ISO 26262. For example, each of the electrical circuits 402 may be representative of (or a portion of) monitoring circuitry, such as the monitoring circuitry 228. The first electrical circuit 402a includes a first DAC 412a, a multiplexer 414, and a comparator 416. The first DAC 412a has an output 418a coupled to a first input 420a of the comparator 416. The first DAC 412a may output a reference signal (e.g., a signal having a certain voltage or current) to the comparator 416. The first DAC 412a may have a range of output voltages and/or currents to set the signal thresholds, for example, for sampling multiple monitor channels (e.g., up to 4 channels) associated with the fourth electrical circuit 404a and/or other electrical circuits.

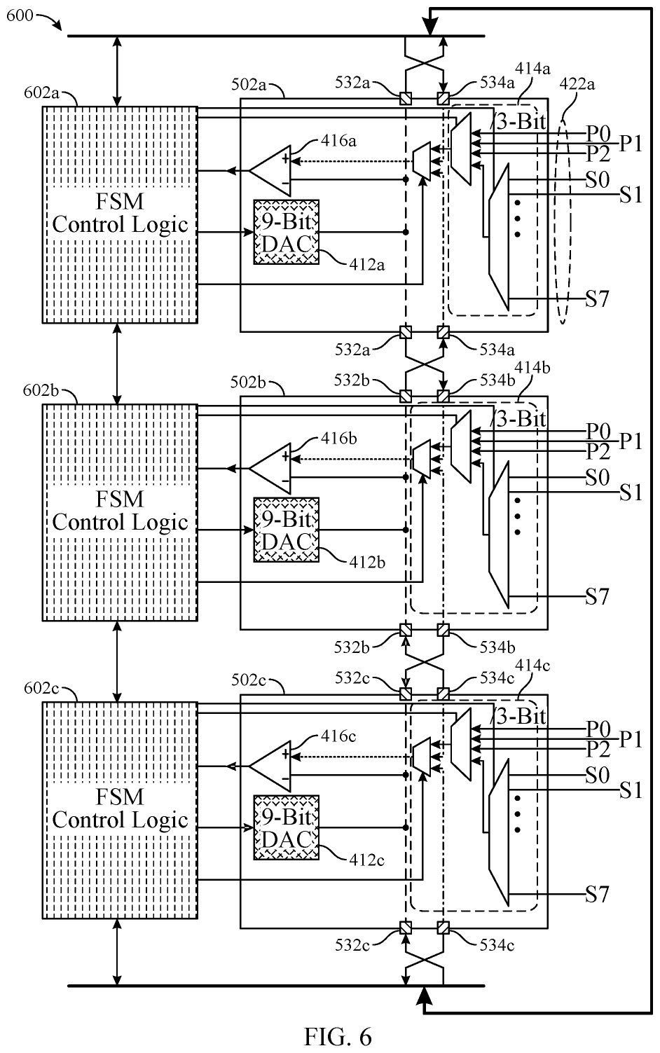

The multiplexer 414 selectively couples multiple inputs 422a, 422b, 422c, 422d (collectively inputs 422) to a single output 424. The multiplexer 414 may select among the several analog or digital inputs 422 and couple the selected input to the single output 424. In some cases, the multiplexer 414 may include multiple multiplexers and/or switches (not shown) arranged in a stack or series. For example, a first multiplexer may have an output coupled to an input of a second multiplexer, which may also have an input coupled to an output of a third multiplexer. The multiplexer 414 may include multiple multiplexers arranged in series with each other, for example, as depicted in FIG. 6, where multiplexers are stacked or nested. The output 424 of the multiplexer 414 is coupled to a second input 420b of the comparator 416. The multiplexer 414 has one or more selection control inputs 426 that indicate which of the inputs 422 to select as the output 424. The one or more control inputs 426 may be coupled to one or more outputs of the processor 406, such that the processor may control the multiplexer 414 and select the output signal coupled to the comparator 416 from the multiplexer 414. In certain aspects, the first input 422a of the multiplexer 414 may be representative of one or more inputs coupled to output(s) of the fourth electrical circuit 404a, which may be a voltage regulator, for example. In some cases, the fourth electrical circuit 404a may have multiple outputs 428 (e.g., voltage or current channels) coupled to separate inputs, such as the first input 422a, of the multiplexer 414. The multiplexer 414 may select a channel among the multiple voltage or current channels of the fourth electrical circuit 404a to evaluate via the comparator 416.

The comparator 416 may compare a signal on the first input 420a to a signal on the second input 420b. The comparator 416 may include a device that compares the voltages and/or currents of the signals received via the inputs 420. The comparator 416 may output a digital signal indicating whether the signal obtained via the second input 420b is greater than the signal obtained via the first input 420a. For example, if the signal received via the second input 420b is greater than the first input 420a, the comparator may output a digital high signal, whereas if the signal received via the second input 420b is less than the first input 420a, the comparator 416 may output a digital low signal. The comparator 416 may have an output 430 coupled to an input of the processor 406, which may evaluate the signal output by the comparator 416. For example, the processor 406 may evaluate whether the first electrical circuit 402a, including the comparator 416, is working properly or may be experiencing a stuck-at (low or high) fault.

The processor 406 may include a microprocessor, a microcontroller, processor, a digital signal processor (DSP), an application specific integrated circuit (ASIC), a field programmable gate array (FPGA) or other programmable logic device (PLD), discrete gate or transistor logic, discrete hardware components, a finite state machine (FSM), or any combination thereof designed to perform the functions described herein. The processor 406 may be in communication with the memory 408, which may store code (e.g., executable instructions) to perform the functions described herein.

The processor 406 may output a signal indicating the selection among the inputs 422 for the output 424, where the output signal of the processor may be provided to the control input(s) 426. As an example, the processor 406 may control when the comparator 416 is operating in monitoring mode (e.g., monitoring the voltage or current level of the fourth electrical circuit 404a) or BIST mode (e.g., verifying the operation integrity of the first electrical circuit 402a including the comparator 416). The sampling of different channels of the fourth electrical circuit 404a and/or DACs 412 via the comparator 416 may be periodic and time multiplexed in order to share the monitoring circuitry across multiple analog circuits and reduce the monitoring circuitry cost. In monitoring mode, the processor 406 may instruct the multiplexer 414 to select the first input 422a as the output 424. In BIST mode, the processor 406 may instruct the multiplexer 414 to select one of the second input 422b or the third input 422c as the output 424. The processor 406 may also control the voltage or current of the signal output by the DACs 412.

The processor 406 may perform one or more actions in response to the signal output by the comparator 416 indicating a fault or successful operation associated with the first electrical circuit. For example, if the comparator 416 indicates a fault, such as an overvoltage, undervoltage, overcurrent, undercurrent, stuck-at-low fault (e.g., when the comparator is stuck outputting a digital low signal), and/or a stuck-at-high fault (e.g., when the comparator 416 is stuck outputting a digital high signal), the processor 406 may perform an action to remedy the fault, reevaluate the fault, indicate the fault (e.g., notify another system(s) or entity), or perform precautionary action(s). The processor 406 may disable the fourth electrical circuit or the respective channel at fault or disable the monitoring circuitry at fault, such as the first electrical circuit 402a.

The first electrical circuit 402a may be representative of the second electrical circuit 402b and/or the third electrical circuit 402c. For example, each of the second electrical circuit 402b and the third electrical circuit 402c includes a respective DAC 412b, 412c, where at least one of the DACs 412b, 412c has an output 418a, 418c coupled to the respective input 422b, 422c of the multiplexer 414. The DACs 412b, 412c may be used in the respective electrical circuits 402b, 402c to output a reference signal to a comparator, such as the comparator 416. The first electrical circuit 402a may have one or more output ports 432a coupled to the output 418a of the first DAC 412a, and so on for the second electrical circuit 402b and/or the third electrical circuit 402c having output port(s) 432b, 432c. The first electrical circuit 402a may have one or more input ports 434a coupled to the inputs 422b, 422c of the multiplexer 414, and so on for the second electrical circuit 402b and/or the third electrical circuit 402c having input port(s) 434b, 434c. It will be appreciated that the input ports 434b, 434c may be coupled to a multiplexer (such as the multiplexer 414) to selectively couple the output 418a of the first DAC 412a to the respective comparator (not shown) of the second electrical circuit 402b and/or the third electrical circuit 402c.

The electrical circuits 402 may be interconnected with each other to facilitate distributed BIST, which may be implemented across two more voltage monitor circuits (e.g., the electrical circuits 402).

The DACs 412b, 412c allow the first electrical circuit 402a to operate in BIST mode to verify the operational integrity (e.g., expected operation) of the first DAC 412a, the comparator 416, and/or the multiplexer 414. For example, the second DAC 412b may output a signal that emulates an overvoltage (or undervoltage, overcurrent, or undercurrent), and the multiplexer 414 may select the second input 422b as the output 424 to test if the comparator 416 successfully detects the fault simulated with the second DAC 412b. Such sharing of the DACs 412b, 412c for BIST(s) may allow a reduction in chip size of circuitry (and/or other enhancements) that is in compliance with certain functional safety standards (such as ISO 26262). Using two or more different neighbor DACs for separate BISTs associated with a particular electrical circuit may allow for enhanced reliability.

In certain aspects, the fourth electrical circuits 404a-c may be an analog circuit, which is monitored by certain monitoring circuitry, such as the monitoring circuitry 228, in compliance with a functional safety standard such as ISO 26262. The fourth electrical circuit 404a may include a voltage regulator or any suitable power supply circuitry, such as a low dropout (LDO) linear voltage regulator, voltage supply, current regulator, or current supply. As an example, the fourth electrical circuit 404a may provide a specific voltage to one or more electrical components 410, such as the SoC 200, the memory 220, the sensors 222, and/or the driver assistance module(s) 224. The fourth electrical circuit 404a may be part of the PMIC 218, for example. In certain cases, the fourth electrical circuit 404a may provide electric power to other circuit(s) and/or device(s). The fourth electrical circuit 404a may be representative of the other fourth electrical circuits 404b, 404c, which may be associated with the second electrical circuit 402b and the third electrical circuit 402c, respectively.

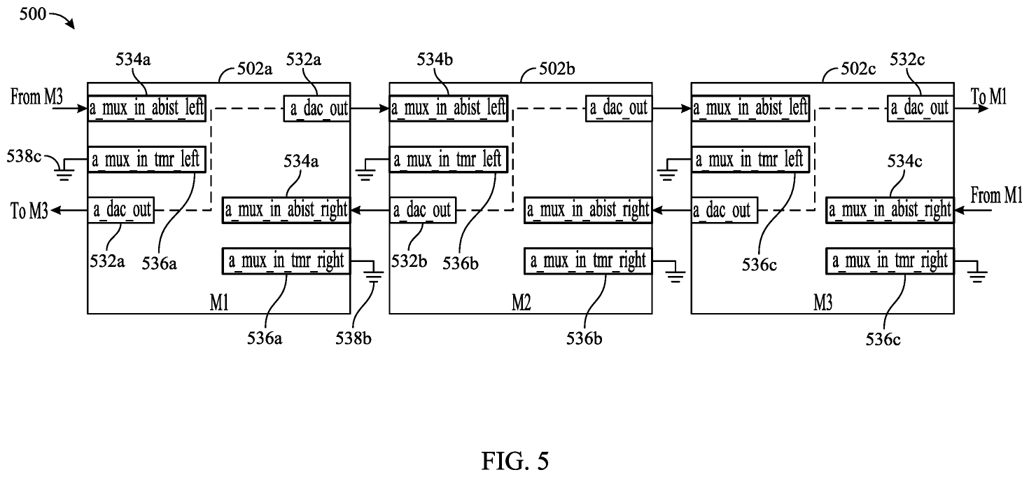

For certain aspects, the multiplexer 414 may have one or more other inputs 422d coupled to other analog electrical circuit(s) (e.g., any of the fourth electrical circuits 404b, 404c) that undergo monitoring by the second electrical circuit 402b and/or the third electrical circuit 402c. The first electrical circuit 402a may include input port(s) 436a coupled to the input 422d of the multiplexer 414. Such connection(s) between the fourth electrical circuits 404b, 404c and the multiplexer 414 may allow the first electrical circuit 402a to monitor the fourth electrical circuits 404b, 404c in addition to or instead of the fourth electrical circuit 404a. Likewise, the second electrical circuit 402b and/or the third electrical circuit 402c may have multiplexer inputs coupled to the fourth electrical circuits 404a, 404b, 404c that undergo monitoring by the respective electrical circuit 402a, 402b, 402c. For example, the monitoring operations associated with a particular analog circuit may be distributed (or rotated) among multiple monitoring circuits (e.g., the electrical circuits 402), as further described herein with respect to FIG. 5.

FIG. 5 is a block diagram of an example distributed BIST architecture 500 illustrating example interconnections among monitoring circuits 502a-c (collectively monitoring circuits 502), such as the electrical circuits 402, to facilitate distributed BIST as described herein with respect to FIG. 4. In this example, the first monitoring circuit 502a may be coupled to the second monitoring circuit 502b and the third monitoring circuit 502c, the second monitoring circuit 502b may be coupled to the first monitoring circuit 502a and the third monitoring circuit 502c, and the third monitoring circuit 502c may be coupled to the first monitoring circuit 502a and the second monitoring circuit 502b. The interconnections associated with the first monitoring circuit 502a may be representative of similar interconnections associated with the second monitoring circuit 502b and/or the third monitoring circuit 502c.

The first monitoring circuit 502a may have DAC output ports 532a (e.g., the output ports 432a) coupled to multiplexer input ports 534b, 534c (e.g., the input ports 434b, 434c) associated with the respective neighboring monitoring circuit 502b, 502c. Likewise, the first monitoring circuit 502a may have multiplexer input ports 534a coupled to DAC output ports 532b, 532c associated with the respective neighboring monitoring circuit 502b, 502c. The first monitoring circuit 502a may have input ports 536a coupled to reference potential nodes 538b, 538c associated with the respective neighboring monitoring circuits 502b, 502c. For example, one of the input ports 536a is coupled to the reference potential node 538b associated with the second monitoring circuit 502b, and another of the input ports 536a is coupled to the reference potential node 538c associated with the third monitoring circuit 502c.

In some cases, the input ports 536a of the first monitoring circuit 502a may be coupled to the output port of the analog circuit (e.g., the fourth electrical circuit 404) associated with the second monitoring circuit 502b and/or the output port of the analog circuit associated with the third monitoring circuit 502c. For example, the input ports 536a may be coupled to the multiplexer (e.g., the multiplexer 414) of the first monitoring circuit 502a (not shown). The input ports 536a and corresponding input ports (536b, 536c) associated with the second monitoring circuit 502b and the third monitoring circuit 502c may allow rotation of the analog circuit being monitored by a particular monitoring circuit and/or distributed monitoring among multiple monitoring circuits. For example, these input ports may allow an analog circuit (e.g., the fourth electrical circuit 404) to be monitored (in some cases simultaneously) by two or more monitoring circuits. Such distributed or rotated monitoring may reduce the number of BISTs performed for a monitoring circuit. If one monitoring circuit has a latent fault, the two other monitoring circuits are likely operating as expected, and a voting mechanism can decide if there is a real fault with the analog circuit or one of the monitors has failed. For example, if two monitoring circuits (e.g., the first monitoring circuit 502a and the second monitoring circuit 502b) indicate that the LDO voltage is correct, and one monitor (e.g., the third monitoring circuit 502c) indicates there is a fault (e.g., an undervoltage or overvoltage), such a result may indicate that the monitoring circuit (e.g., the third monitoring circuit 502c) indicating a fault has failed.

FIG. 6 is a more detailed block diagram of an example monitoring architecture 600 illustrating example interconnections among the monitoring circuits 502 shown in FIG. 5 for distributed BIST. In this example, the monitoring circuit 502a may be arranged in a chip package (not shown), such that the first monitoring circuit 502a is adjacent to the second monitoring circuit 502b; the second monitoring circuit 502b is arranged between the first monitoring circuit 502a and the third monitoring circuit 502c; and the third monitoring circuit 502c is arranged adjacent to the second monitoring circuit 502b. The monitoring circuits 502 may be arranged on the same layer or different layers of the chip package, for example. The first monitoring circuit 502a may be coupled to the third monitoring circuit 502c such that the first monitoring circuit 502a and the third monitoring circuit 502c are treated as being adjacent to each other for purposes of performing distributed BISTs.

As shown, the DAC output ports 532a are coupled to the multiplexer input ports 534b, 534b associated with the respective monitoring circuits 502b, 502c; and so on for the respective DAC output ports 532b, 532c. The multiplexer input ports 534a are coupled to the DAC output ports 532b, 532c; and so on for the respective multiplexer input ports 534b, 534c.

As an example, the BIST associated with the first monitoring circuit 502a may be performed by temporarily using the DAC 412b, 412c of the second monitoring circuit 502b or the third monitoring circuit 502c, respectively. Once the BIST check is completed, the monitoring circuits 502 may operate independently, until another BIST is performed.

Control logic 602a-c (collectively control logic 602) may be coupled to the respective monitoring circuit 502. The processor 406 and the memory 408 may be representative of the control logic 602, such that the control logic 602 controls when the BIST is performed at any of the monitoring circuits 502 using a DAC from a neighboring monitoring circuit 502. In certain cases, the time slots used for monitoring and performing BISTs may be aligned across the monitoring circuits that share DACs for the distributed BISTs.

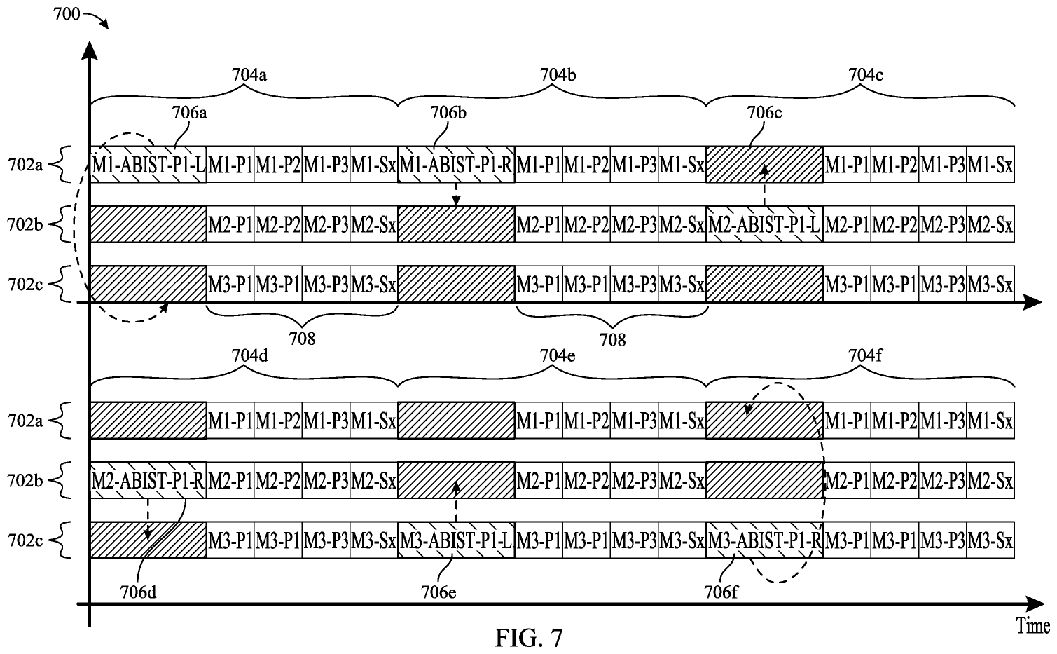

FIG. 7 is a timing diagram 700 illustrating example timelines 702 for time division multiplexing the BIST and monitoring across multiple circuits, such as the monitoring circuits 502. In this example, the timelines 702 include a first timeline 702a associated with first monitoring circuit 502a, a second timeline 702b associated with the second monitoring circuit 502b, and a third timeline 702c associated with the third monitoring circuit 502c. In a first monitoring frame 704a, a BIST as described herein with respect to FIGS. 3 and 4 may be performed on the first monitoring circuit 502a using the DAC of the third monitoring circuit 502c in a first testing occasion 706a. The subsequent occasions 708 of the first monitoring frame 704a may be used to monitor various output channels of the respective voltage regulators. For example, each of the monitoring circuits 502 may monitor primary channels (e.g., P1, P2, and P3) and/or secondary channel(s) (e.g., Sx) associated with the voltage regulator in separate monitoring occasions. Examples of such channels are depicted in FIG. 6 with respect to the inputs 422a.

In a second monitoring frame 704b, a BIST may be performed on the first monitoring circuit 502a using the DAC of the second monitoring circuit 502b in a second testing occasion 706b. Performing the BISTs on the first monitoring circuit 502a using DACs from different monitoring circuits may allow for BIST redundancy to further verify the result(s) associated with the BIST(s) performed with a particular DAC. In a third monitoring frame 704c, a BIST may be performed on the second monitoring circuit 502b using the DAC of the first monitoring circuit 502a in a third testing occasion 706c, and so on for the subsequent testing occasions 706d-f associated with the respective monitoring frames 704d-f. In some cases, the monitoring frames 704a-f may occur in a time sequence, such that the second monitoring frame 704b occurs after the first monitoring frame 704a, and so on for the subsequent monitoring frames 704c-f occurring one after the other.

In certain cases, the first set of monitoring frames 704a-704c may occur in parallel with the second set of monitoring frames 704d-704f. For example, in the first testing occasion 706a and the fourth testing occasion 706d, separate BISTs may be performed on the first monitoring circuit 502a and the second monitoring circuit 502b using the DAC of the third monitoring circuit 502c. In this example, the DAC of the third monitoring circuit 502c provides a signal to the first monitoring circuit 502a and the second monitoring circuit 502b, and so on for the subsequent monitoring frames 704b, 704c, 704e, 704f. Thus, it will be appreciated that the DAC of a monitoring circuit may be used to perform BISTs on multiple monitoring circuits concurrently as depicted in FIG. 7.

In certain aspects, the distributed testing architecture described herein may be used to test and/or monitor any of various characteristics associated with a circuit, such as voltage, current, power, temperature, etc. Pairing multiple monitor circuits can be used to ensure the circuits stay within safe operating conditions (e.g., a safe operating area associated with a multi-dimensional graph temperature, voltage, and current). For example, as monitoring circuits may be arranged in different locations across a circuit package, the monitoring circuits may be exposed to differing temperatures, such that variations in operating performance across the monitoring circuits may be an indication of the differing temperatures, and so on for voltages, currents, etc. The operating conditions may be represented as a complex multi-dimensional function of multiple variables (temperature, voltage, current, etc.) associated with the monitoring circuits, for example.

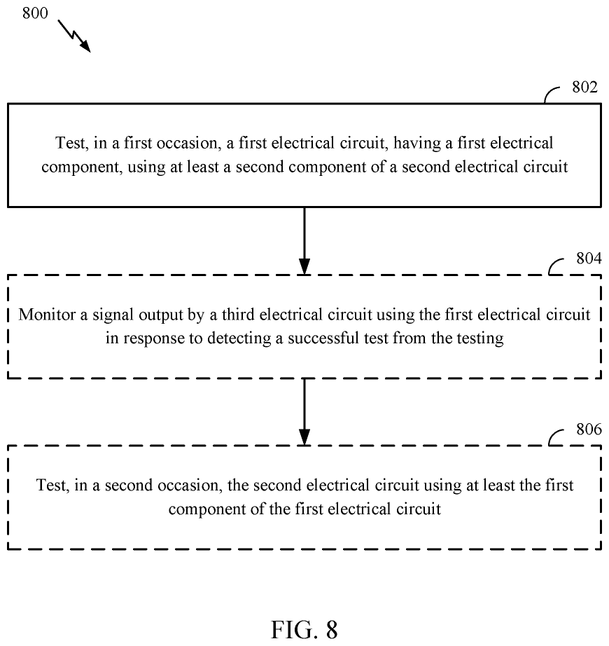

FIG. 8 is a flow diagram depicting example operations 800 for testing circuitry. The operations 800 may be performed by the electrical circuits 402 and/or the monitoring circuits 502, as described herein with respect to FIGS. 5-7.

The operations 800 may optionally begin, at block 802, where a first electrical circuit (e.g., the first electrical circuit 402a or the first monitoring circuit 502a), having a first component (e.g., the first DAC 412a) is tested, in a first occasion (e.g., the second testing occasion 706b), using at least a second component (e.g., the second DAC 412b) of a second electrical circuit (e.g., the second electrical circuit 402b or the second monitoring circuit 502b). To test the first electrical circuit, a first voltage output by the first component may be compared to a second voltage output by the second component, for example, using the comparator 416. Testing the first electrical circuit may include performing a BIST associated with the first electrical circuit, for example, as described herein with respect to FIGS. 3 and 4.

Optionally, at block 804, a signal output by a third electrical circuit (e.g., the fourth electrical circuit 404 or a voltage regulator) may be monitored using the first electrical circuit in response to detecting a successful test from the testing. A successful test may include the comparator successfully detecting a particular state, such as an overvoltage, undervoltage, overcurrent, and/or undercurrent. The signal may be monitored based on a reference signal output by the first component.

Optionally, at block 806, the second electrical circuit may be tested, in a second occasion (e.g., the third testing occasion 706c), using at least the first component of the first electrical circuit. For example, a first voltage output by the first component may be compared to a second voltage output by the second component, for example, using a comparator associated with the second electrical circuit. In some cases, the BISTs and monitoring may be arranged into time slots or occasions, for example, as depicted in FIG. 7. For example, the monitoring at block 804 may occur in a third occasion (e.g., the respective subsequent occasions 708 in the second monitoring frame 704b).

To test the first electrical circuit, a plurality of operational states associated with the first electrical circuit may be tested, where each of the plurality of operational states may be associated with a different voltage level, a different current level, a different temperature, or a combination thereof. For example, the testing at block 802 may include testing any of a range of voltages, a range of currents, and/or a range of temperatures associated with the electrical circuits. In certain aspects, the monitoring circuits may be used to monitor a plurality of properties associated an electrical circuit, for example, via multi-dimensional monitoring. As an example, a plurality of properties associated with a third electrical circuit (e.g., the fourth electrical circuit 404a) may be monitored through monitoring a signaling output by third electrical circuit using the first electrical circuit and the second electrical circuit.

To monitor the signal at block 804, the signal may be compared to the reference signal, for example, using the comparator 416. For example, a voltage level of the signal may be monitored using a comparator (e.g., the comparator 416) of the first electrical circuit, where the comparator has a first input (e.g., the first input 420a) coupled to the first component and a second input (e.g., the second input 420b) selectively coupled to the second component and an output of the third electrical circuit (e.g., via the multiplexer 414). The comparator may indicate whether the signal is greater than or equal to the reference signal.

In some cases, the circuit monitoring may be distributed among multiple monitoring circuits, for example, as described herein with respect to FIGS. 4 and 5. For example, a first signal output by a third electrical circuit may be monitored using the first electrical circuit based on a first reference signal output by the first component. A second signal output by the third electrical circuit may be monitored using the second electrical circuit based on a second reference signal output by the second component. In some cases, a third signal output by the third electrical circuit may be monitored using a fourth electrical circuit (e.g., the third electrical circuit 402c) based on a third reference signal output by a third component (e.g., the third DAC 412c). In certain aspects, the first signal, second signal, and the third signal may be the same signal output by the third electrical circuit or different signals (e.g., via different channels or the same channel at different times).

The monitoring results of the monitoring circuits may be compared amongst each other. Any discrepancies among the results may be indicate a fault with the monitoring circuit (e.g., the first electrical circuit 402a) or the circuit under monitoring (e.g., the fourth electrical circuit 404a), as described herein with respect to FIG. 5. In some cases, a voting mechanism may be used to determine if there is a fault with the circuit under monitoring. For example, a fault with the circuit under monitoring may be considered to occur when a majority of the monitoring circuits indicate there is a fault (e.g., undervoltage or overvoltage) with the circuit under monitoring.

In certain aspects, a third circuit may be tested using a distributed testing operation as described herein. A third electrical circuit (e.g., the third electrical circuit 402c or the third monitoring circuit 502c) may be tested, in a third occasion (e.g., the fifth testing occasion 706e), using at least the second component of the second electrical circuit or the first component of the first electrical circuit.

In some aspects, the first electrical circuit may be tested again using a different component to provide redundancy in the components used and testing performed. The first circuit may be tested, in a third occasion (e.g., the first testing occasion 706a), using at least a third component (e.g., the DAC 412c) of a third electrical circuit (e.g., the third electrical circuit 402c or the third monitoring circuit 502c).

In certain aspects, the distributed testing described herein may comply with a particular functional safety standard, for example, implemented for electrical components in a vehicle, aircraft, watercraft, spacecraft, medical device, electronic device, military device, etc. For example, the testing associated with the first electrical circuit may be in compliance with a functional safety standard (e.g., ISO 26262) associated with a vehicle, aircraft, watercraft, spacecraft, etc.

The circuits associated with the operations 800 may include any of the circuits described herein with respect to FIGS. 2-6. For example, the first component includes a first DAC (e.g., the first DAC 412a). The second component includes a second DAC (e.g., the second DAC 412b). The first electrical circuit includes a comparator (e.g., the comparator 416) having a first input (e.g., the first input 420a) coupled to an output of the first DAC and a second input (e.g., the second input 420b) selectively coupled to an output of the second DAC (e.g., via the multiplexer 414).

The various operations of methods described above may be performed by any suitable means capable of performing the corresponding functions. The means may include various hardware and/or software component(s) and/or module(s), including, but not limited to a circuit, an application specific integrated circuit (ASIC), or processor. Means for testing and means for monitoring may include any of the devices, modules, circuits, and/or components associated therewith described herein with respect to FIGS. 1-6. For example, means for testing may include electrical circuits such as the first electrical circuit 402a and the second electrical circuit 402b. Means for monitoring may include electrical circuits such as the first electrical circuit 402a and the fourth electrical circuit 404.

### Example Aspects

Implementation examples are described in the following numbered aspects:

Aspect 1: A method of testing circuitry, comprising: testing, in a first occasion, a first electrical circuit, having a first component, using at least a second component of a second electrical circuit; and testing, in a second occasion, the second electrical circuit using at least the first component of the first electrical circuit.

Aspect 2: The method of Aspect 1, wherein testing the first electrical circuit comprises testing a plurality of operational states associated with the first electrical circuit.

Aspect 3: The method of Aspect 2, wherein each of the plurality of operational states is associated with a different voltage level, a different current level, a different temperature, or a combination thereof.

Aspect 4: The method according to any of Aspects 1-3, wherein testing the first electrical circuit comprises comparing a first voltage output by the first component to a second voltage output by the second component.

Aspect 5: The method according to any of Aspects 1-4, wherein testing the first electrical circuit comprises performing a built-in self-test associated with the first electrical circuit.

Aspect 6: The method according to any of Aspects 1-5, wherein: the first component includes a first digital-to-analog-converter (DAC); the second component includes a second DAC; and the first electrical circuit includes a comparator having a first input coupled to an output of the first DAC and a second input selectively coupled to an output of the second DAC.

Aspect 7: The method according to any of Aspects 1-6, further comprising monitoring a signal output by a third electrical circuit using the first electrical circuit based on a reference signal output by the first component.

Aspect 8: The method of Aspect 7, wherein monitoring the signal comprises comparing the signal to the reference signal.

Aspect 9: The method of Aspect 7 or 8, wherein monitoring the signal comprises monitoring a voltage level of the signal using a comparator of the first electrical circuit, the comparator having a first input coupled to the first component and a second input selectively coupled to the second component and an output of the third electrical circuit.

Aspect 10: The method according to any of Aspects 1-9, further comprising monitoring a plurality of properties associated with a third electrical circuit through monitoring a signaling output by the third electrical circuit using the first electrical circuit and the second electrical circuit.

Aspect 11: The method according to any of Aspects 1-10, further comprising: monitoring a first signal output by a third electrical circuit using the first electrical circuit based on a first reference signal output by the first component; and monitoring a second signal output by the third electrical circuit using the second electrical circuit based on a second reference signal output by the second component.

Aspect 12: The method according to any of Aspects 1-11, further comprising testing, in a third occasion, a third electrical circuit using at least the second component of the second electrical circuit or the first component of the first electrical circuit.

Aspect 13: The method according to any of Aspects 1-12, further comprising testing, in a third occasion, the first electrical circuit using at least a third component of a third electrical circuit.

Aspect 14: The method according to any of Aspects 1-13, wherein testing the first electrical circuit comprises testing the first electrical circuit in compliance with a functional safety standard associated with a vehicle.

Aspect 15: A method of testing circuitry, comprising: testing, in a first occasion, a first electrical circuit, having a first electrical component, using at least a second component of a second electrical circuit; and monitoring a signal output by a third electrical circuit using the first electrical circuit in response to detecting a successful test from the testing.

Aspect 16: The method of Aspect 15, further comprising testing, in a second occasion, the first electrical circuit using at least a third component of a fourth electrical circuit, and wherein the monitoring occurs in a third occasion.

Aspect 17: The method of Aspect 15 or 16, wherein testing the first electrical circuit comprises testing the first electrical circuit in compliance with a functional safety standard associated with a vehicle.

Aspect 18: An apparatus for testing circuitry, comprising: a first electrical circuit having a first component; a second electrical circuit having a second component selectively coupled to the first electrical circuit; a memory; and a processor coupled to the memory, the processor being configured to: test, in a first occasion, the first electrical circuit using at least the second component, and test, in a second occasion, the second electrical circuit using at least the first component.

Aspect 19: The apparatus of Aspect 18, wherein to test the first electrical circuit, the processor is further configured to test a plurality of operational states associated with the first electrical circuit.

Aspect 20: The apparatus of Aspect 19, wherein each of the plurality of operational states is associated with a different voltage level, a different current level, a different temperature, or a combination thereof.

Aspect 21: The apparatus according to any of Aspects 18-20, wherein to test the first electrical circuit, the processor is further configured to compare a first voltage output by the first component to a second voltage output by the second component.

Aspect 22: The apparatus according to any of Aspects 18-21, wherein to test the first electrical circuit, the processor is further configured to perform a built-in self-test associated with the first electrical circuit.

Aspect 23: The apparatus according to any of Aspects 18-22, wherein: the first component includes a first digital-to-analog-converter (DAC); the second component includes a second DAC; and the first electrical circuit includes a comparator having a first input coupled to an output of the first DAC and a second input selectively coupled to an output of the second DAC.

Aspect 24: The apparatus according to any of Aspects 18-23, further comprising a third electrical circuit configured to output a signal, wherein the processor is further configured to monitor the signal output by the third electrical circuit using the first electrical circuit based on a reference signal output by the first component.

Aspect 25: The apparatus of Aspect 24, wherein to monitor the signal, the processor is further configured to compare the signal to the reference signal.

Aspect 26: The apparatus of Aspect 24 or 25, further comprising: a comparator having a first input coupled to the first component and a second input selectively coupled to the second component and an output of the third electrical circuit, wherein to monitor the signal, the processor is further configured to monitor a voltage level of the signal using the comparator.

Aspect 27: The apparatus according to any of Aspects 18-26, wherein the processor is further configured to test, in a third occasion, a third electrical circuit using at least the second component of the second electrical circuit or the first component of the first electrical circuit.

Aspect 28: The apparatus according to any of Aspects 18-27, further comprising a third electrical circuit having a third component, wherein the processor is further configured to test, in a third occasion, the first electrical circuit using at least the third component of the third electrical circuit.

Aspect 29: The apparatus according to any of Aspects 18-28, wherein to test the first electrical circuit, the processor is further configured to test the first electrical circuit in compliance with a functional safety standard associated with a vehicle.

Aspect 30: An apparatus, comprising: a first electrical circuit having a first digital-to-analog converter (DAC) and a first comparator, wherein the first DAC is coupled to a first input of the first comparator; a second electrical circuit having a second DAC selectively coupled to a second input of the first comparator; and a third electrical circuit having an output selectively coupled to the second input of the first comparator.

Aspect 31: The apparatus of Aspect 30, wherein: the first electrical circuit further comprises a multiplexer having a first input coupled to the output of the third electrical circuit, a second input coupled to an output of the second DAC, and an output coupled to the second input of the first comparator; and the third electrical circuit comprises a voltage regulator or a current regulator.

Aspect 32: The apparatus of Aspect 30 or 31, wherein the first electrical circuit, the second electrical circuit, and the third electrical circuit are in compliance with a functional safety standard associated with a vehicle.

Aspect 33: An apparatus, comprising: a memory comprising computer-executable instructions; and one or more processors configured to execute the computer-executable instructions and cause the apparatus to perform a method in accordance with any of Aspects 1-17.

Aspect 34: An apparatus, comprising means for performing a method in accordance with any of Aspects 1-17.

Aspect 35: A non-transitory computer-readable medium comprising computer-executable instructions that, when executed by one or more processors of a processing system, cause the processing system to perform a method in accordance with any of Aspects 1-17.

Aspect 36: A computer program product embodied on a computer-readable storage medium comprising code for performing a method in accordance with any of Aspects 1-17.

### Additional Considerations

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. A method of testing circuitry, comprising:
testing, in a first occasion, a first electrical circuit, having a first component, using at least a second component of a second electrical circuit; and
testing, in a second occasion, the second electrical circuit using at least the first component of the first electrical circuit.

2. The method of claim 1, wherein testing the first electrical circuit comprises testing a plurality of operational states associated with the first electrical circuit.

3. The method of claim 2, wherein each of the plurality of operational states is associated with a different voltage level, a different current level, a different temperature, or a combination thereof.

4. The method of claim 1, wherein testing the first electrical circuit comprises comparing a first voltage output by the first component to a second voltage output by the second component.

5. The method of claim 1, wherein testing the first electrical circuit comprises performing a built-in self-test associated with the first electrical circuit.

6. The method of claim 1, wherein:
the first component includes a first digital-to-analog-converter (DAC);
the second component includes a second DAC; and
the first electrical circuit includes a comparator having a first input coupled to an output of the first DAC and a second input selectively coupled to an output of the second DAC.

7. The method of claim 1, further comprising monitoring a signal output by a third electrical circuit using the first electrical circuit based on a reference signal output by the first component.

8. The method of claim 7, wherein monitoring the signal comprises comparing the signal to the reference signal.

9. The method of claim 7, wherein monitoring the signal comprises monitoring a voltage level of the signal using a comparator of the first electrical circuit, the comparator having a first input coupled to the first component and a second input selectively coupled to the second component and an output of the third electrical circuit.

10. The method of claim 1, further comprising monitoring a plurality of properties associated with a third electrical circuit through monitoring a signaling output by the third electrical circuit using the first electrical circuit and the second electrical circuit.

11. The method of claim 1, further comprising:
monitoring a first signal output by a third electrical circuit using the first electrical circuit based on a first reference signal output by the first component; and
monitoring a second signal output by the third electrical circuit using the second electrical circuit based on a second reference signal output by the second component.

12. The method of claim 1, further comprising testing, in a third occasion, a third electrical circuit using at least the second component of the second electrical circuit or the first component of the first electrical circuit.

13. The method of claim 1, further comprising testing, in a third occasion, the first electrical circuit using at least a third component of a third electrical circuit.

14. The method of claim 1, wherein testing the first electrical circuit comprises testing the first electrical circuit in compliance with a functional safety standard associated with a vehicle.

15. A method of testing circuitry, comprising:
testing, in a first occasion, a first electrical circuit, having a first electrical component, using at least a second component of a second electrical circuit; and
monitoring a signal output by a third electrical circuit using the first electrical circuit in response to detecting a successful test from the testing.

16. The method of claim 15, further comprising:
testing, in a second occasion, the first electrical circuit using at least a third component of a fourth electrical circuit; and
wherein the monitoring occurs in a third occasion.

17. An apparatus for testing circuitry, comprising:
a first electrical circuit having a first component;
a second electrical circuit having a second component selectively coupled to the first electrical circuit;
a memory; and
a processor coupled to the memory, the processor being configured to:
test, in a first occasion, the first electrical circuit using at least the second component, and
test, in a second occasion, the second electrical circuit using at least the first component.

18. The apparatus of claim 17, wherein to test the first electrical circuit, the processor is further configured to test a plurality of operational states associated with the first electrical circuit.

19. The apparatus of claim 18, wherein each of the plurality of operational states is associated with a different voltage level, a different current level, a different temperature, or a combination thereof.

20. The apparatus of claim 17, wherein to test the first electrical circuit, the processor is further configured to compare a first voltage output by the first component to a second voltage output by the second component.

21. The apparatus of claim 17, wherein to test the first electrical circuit, the processor is further configured to perform a built-in self-test associated with the first electrical circuit.

22. The apparatus of claim 17, wherein:
the first component includes a first digital-to-analog-converter (DAC);
the second component includes a second DAC; and
the first electrical circuit includes a comparator having a first input coupled to an output of the first DAC and a second input selectively coupled to an output of the second DAC.

23. The apparatus of claim 17, further comprising a third electrical circuit configured to output a signal, wherein the processor is further configured to monitor the signal output by the third electrical circuit using the first electrical circuit based on a reference signal output by the first component.

24. The apparatus of claim 23, wherein to monitor the signal, the processor is further configured to compare the signal to the reference signal.

25. The apparatus of claim 23, further comprising:
a comparator having a first input coupled to the first component and a second input selectively coupled to the second component and an output of the third electrical circuit, wherein to monitor the signal, the processor is further configured to monitor a voltage level of the signal using the comparator.

26. The apparatus of claim 17, wherein the processor is further configured to test, in a third occasion, a third electrical circuit using at least the second component of the second electrical circuit or the first component of the first electrical circuit.

27. The apparatus of claim 17, further comprising a third electrical circuit having a third component, wherein the processor is further configured to test, in a third occasion, the first electrical circuit using at least the third component of the third electrical circuit.

28. The apparatus of claim 17, wherein to test the first electrical circuit, the processor is further configured to test the first electrical circuit in compliance with a functional safety standard associated with a vehicle.

29. An apparatus, comprising:
a first electrical circuit having a first digital-to-analog converter (DAC) and a first comparator, wherein the first DAC is coupled to a first input of the first comparator;
a second electrical circuit having a second DAC selectively coupled to a second input of the first comparator; and
a third electrical circuit having an output selectively coupled to the second input of the first comparator.

30. The apparatus of claim 29, wherein:
the first electrical circuit further comprises a multiplexer having a first input coupled to the output of the third electrical circuit, a second input coupled to an output of the second DAC, and an output coupled to the second input of the first comparator;
the third electrical circuit comprises a voltage regulator or a current regulator; and
the first electrical circuit, the second electrical circuit, and the third electrical circuit are in compliance with a functional safety standard associated with a vehicle.
